(19) United States
(12) Patent Application Publication
(10) Pub. No.: US 2025/0316477 A1
(43) Pub. Date: Oct. 9, 2025

(54) FILM FORMING METHOD

(71) Applicant: Tokyo Electron Limited, Tokyo (JP)

(72) Inventors: Yosuke WATANABE, Yamanashi (JP); Yoshihiro TAKEZAWA, Yamanashi (JP); Tatsuya MIYAHARA, Yamanashi (JP)

(21) Appl. No.: 19/088,033

(22) Filed: Mar. 24, 2025

(30) Foreign Application Priority Data
Apr. 5, 2024 (JP) 2024-061702

(51) Int. Cl. H01L 21/02

(52) U.S. Cl. CPC H01L 21/02672

(57) ABSTRACT

To provide a technique capable of controlling a nickel concentration in a silicon film, a film forming method includes: preparing a substrate having an amorphous silicon film on a surface of the substrate; changing a surface state of the amorphous silicon film; and after the changing, diffusing nickel into the amorphous silicon film by supplying a nickel raw material gas to the amorphous silicon film.

### CROSS-REFERENCE TO RELATED APPLICATION

The present application claims priority under 35 U.S.C. § 119 to Japanese Patent Application No. 2024-061702, filed Apr. 5, 2024, the contents of which are incorporated herein by reference in their entireties.

### BACKGROUND OF THE INVENTION

### Field of the Invention

This disclosure relates to a film forming method.

### Description of the Related Art

There is a known technology for transforming an amorphous silicon film into a polycrystalline silicon film by adsorbing nickel particles on the surface of the amorphous silicon film and then performing annealing (see, for example, Japanese Patent Application Laid-Open Publication No. 2011-60908).

### SUMMARY OF THE INVENTION

The present disclosure provides a technology capable of controlling the nickel concentration in a silicon film.

A film forming method according to one aspect of the present disclosure includes: preparing a substrate having an amorphous silicon film on a surface of the substrate; changing a surface state of the amorphous silicon film; and after the changing, diffusing nickel into the amorphous silicon film by supplying a nickel raw material gas to the amorphous silicon film.

According to the present disclosure, it is possible to control the nickel concentration in a silicon film.

### BRIEF DESCRIPTION OF THE DRAWINGS

FIG. 1 is a flowchart showing a film forming method according to an embodiment;

FIG. 2 is a cross-sectional view showing a film forming method according to an embodiment;

FIG. 3 is a diagram showing the result of analyzing a surface reaction in a diffusion step by thermodynamic calculation;

FIG. 4 is a schematic diagram showing an example of a surface reaction in a diffusion step;

FIG. 5 is a schematic diagram showing another example of a surface reaction in a diffusion step;

FIG. 6 is a cross-sectional view showing a film forming apparatus according to an embodiment;

FIG. 7 is a diagram showing an example of a result of comparing a nickel concentration in an amorphous silicon film;

FIG. 8 is a diagram showing an example of temperature dependency of a nickel concentration in an amorphous silicon film; and

FIG. 9 is a diagram showing another example of temperature dependency of a nickel concentration in an amorphous silicon film.

### DETAILED DESCRIPTION OF THE DISCLOSURE

Hereinafter, non-limiting exemplary illustrative embodiments of the present disclosure will be described with reference to the attached drawings. In all of the attached drawings, the same or corresponding members or parts will be denoted by the same or corresponding reference numerals, and duplicate descriptions thereof will be omitted.

### FILM FORMING METHOD

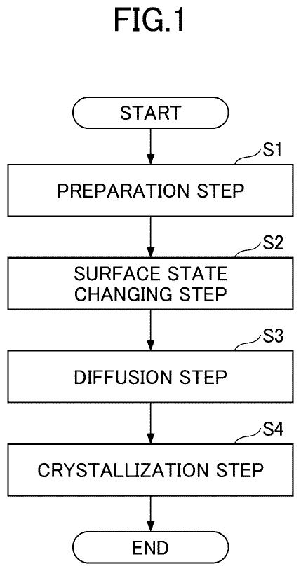

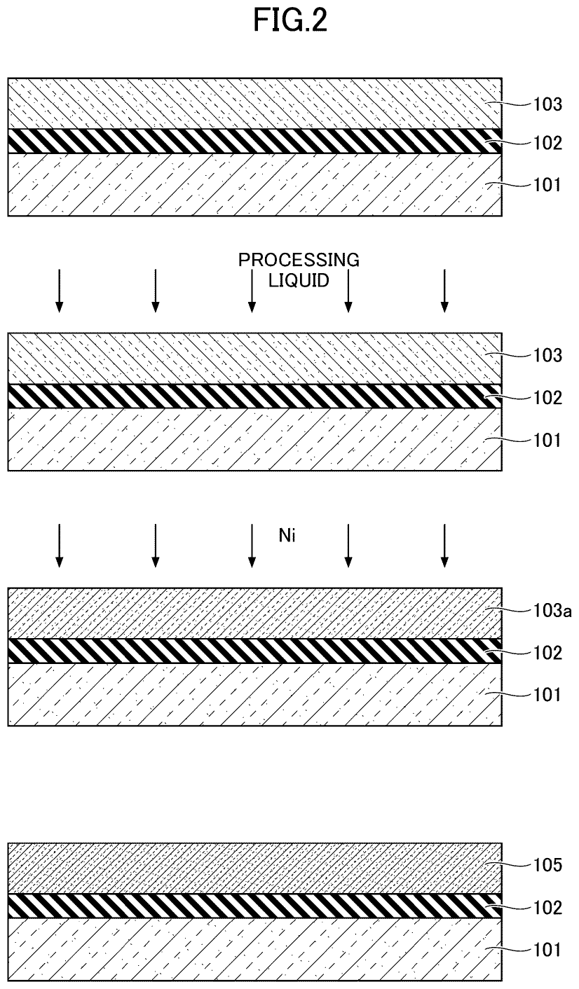

Referring to FIGS. 1 to 5, a film forming method according to an embodiment will be described. The following description will be based on a case of forming a polycrystalline silicon film on a substrate, as an example. Polycrystalline silicon films can be used as, for example, channel silicon films of three-dimensional NAND flash memories. FIG. 1 is a flowchart showing the film forming method according to the present embodiment. FIG. 2 is a cross-sectional view showing the film forming method according to the present embodiment.

As shown in FIG. 1, the film forming method according to the present embodiment includes a preparation step S1, a surface state changing step S2, a diffusion step S3, and a crystallization step S4.

In the preparation step S1, a substrate 101 is prepared as shown in the uppermost view of FIG. 2. The substrate 101 is, for example, a silicon wafer. An oxide film 102 and an amorphous silicon film 103 may be formed on the substrate 101 in this order. The oxide film 102 is, for example, a silicon oxide film. The amorphous silicon film 103 can be formed by Chemical Vapor Deposition (CVD) using, for example, a silicon-containing gas. The silicon-containing gas is, for example, diisopropyl aminosilane (DIPAS), disilane, monosilane, or combinations thereof.

The surface state changing step S2 is performed after the preparation step S1. In the surface state changing step S2, the surface state of the amorphous silicon film 103 is changed. The surface state changing step S2 may include adjusting the ratio of Si—OH groups to Si—H groups on the surface of the amorphous silicon film 103. The surface state changing step S2 may include adjusting the ratio of Si—OH groups to Si—H groups by supplying a processing liquid to the amorphous silicon film 103, as shown in the second uppermost view of FIG. 2. When the processing liquid is APM (a mixture of ammonia, hydrogen peroxide, and water), the ratio of Si—OH groups to Si—H groups can be increased. When the processing liquid is DHF (dilute hydrofluoric acid), the ratio of Si—OH groups to Si—H groups can be decreased. In the surface state changing step S2, APM may be supplied after DHF is supplied to the amorphous silicon film 103.

The diffusion step S3 is performed after the surface state changing step S2. In the diffusion step S3, as shown in the second lowermost view of FIG. 2, a nickel raw material gas is supplied to the substrate 101 to diffuse nickel (Ni) into the amorphous silicon film 103. Thus, an amorphous silicon film in the interior of which nickel has diffused (hereinafter referred to as “nickel-containing amorphous silicon film 103a”) is formed. The nickel raw material gas can be generated by, for example, vaporizing a liquid nickel raw material. The liquid nickel raw material is, for example, (EtCp)₂Ni [Ni(C₂H₅C₅H₄)₂], NiPF₃ [Ni(PF₃)₄], CpAllylNi [(C₃H₅)(C₅H₅)Ni], or Ni(CO)₄. The nickel raw material gas can be generated by, for example, sublimating a solid nickel raw material. The solid nickel raw material is, for example, (MeCp)₂Ni [Ni(CH₃C₅H₄)₂]. For example, when (EtCp)₂Ni is used as the nickel raw material, the substrate temperature is 150° C. or higher and 300° C. or lower. In the diffusion step S3, the amount of nickel to be diffused into the nickel-containing amorphous silicon film 103a can be adjusted by controlling the flow rate at which the nickel raw material gas is supplied. For example, the diffusion step S3 is continuously performed in the same processing chamber as that in the preparation step S1. The diffusion step S3 may be performed in a processing chamber different from that in the preparation step S1.

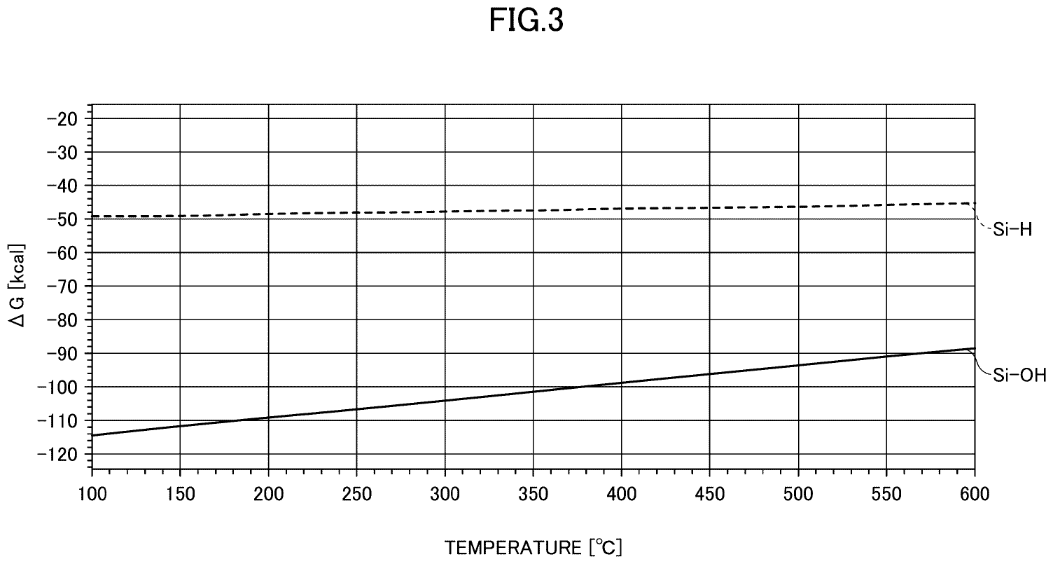

A surface reaction of the amorphous silicon film 103 in the diffusion step S3 will be described with reference to FIGS. 3 to 5. A surface reaction of the amorphous silicon film 103 in the diffusion step S3 is considered to proceed as follows.

FIG. 3 is a diagram showing the result of analyzing the surface reaction in the diffusion step S3 by thermodynamic calculation. In FIG. 3, the horizontal axis represents temperature [° C.], and the vertical axis represents the amount of change in Gibbs free energy ΔG [kcal]. In FIG. 3, the solid line indicates the amount of change in Gibbs free energy of a reaction for forming Si—Ni groups from Si—OH groups and the nickel raw material gas, and the broken line indicates the amount of change in Gibbs free energy of a reaction for forming Si—Ni groups from Si—H groups and the nickel raw material gas.

As shown in FIG. 3, the amount of change in Gibbs free energy of the reaction for forming Si—Ni groups from Si—OH groups and the nickel raw material gas and the amount of change in Gibbs free energy of the reaction for forming Si—Ni groups from Si—H groups and the nickel raw material gas are both negative values. The absolute value of the amount of change in Gibbs free energy of the reaction for forming Si—Ni groups from Si—OH groups and the nickel raw material gas is greater than the absolute value of the amount of change in Gibbs free energy of the reaction for forming Si—Ni groups from Si—H groups and the nickel raw material gas. From this result, it can be regarded that the reaction for forming Si—Ni groups from Si—OH groups and the nickel raw material gas proceeds more easily than the reaction for forming Si—Ni groups from Si—H groups and the nickel raw material gas.

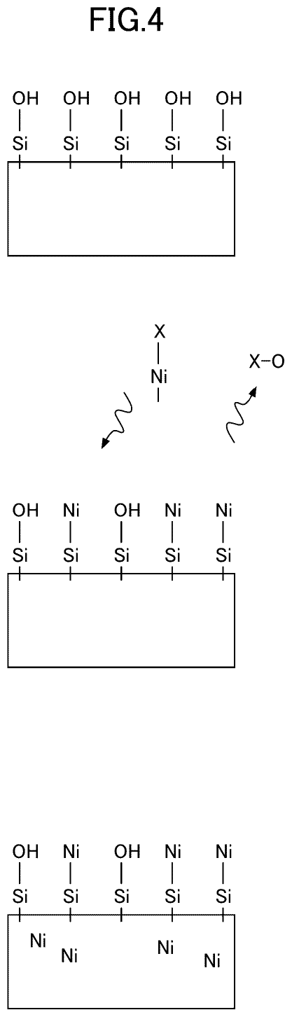

FIG. 4 is a schematic diagram showing an example of the surface reaction in the diffusion step S3. FIG. 4 shows the surface reaction in the diffusion step S3 when APM is used as the processing liquid in the surface state changing step S2. The upper view of FIG. 4 shows the surface state of the amorphous silicon film 103 before the diffusion step S3 is performed. The middle view of FIG. 4 shows the surface state of the amorphous silicon film 103 after a first time has elapsed since the start of the diffusion step S3. The lower view of FIG. 4 shows the surface state of the amorphous silicon film 103 after a second time has elapsed since the start of the diffusion step S3. The second time is longer than the first time.

As shown in the upper view of FIG. 4, when APM is supplied to the amorphous silicon film 103, the ratio of Si—OH groups to Si—H groups increases on the surface of the amorphous silicon film 103. As described above, the reaction for forming Si—Ni groups from Si—OH groups and the nickel raw material gas proceeds more easily than the reaction for forming Si—Ni groups from Si—H groups and the nickel raw material gas. Therefore, as shown in the middle view of FIG. 4, when the nickel raw material gas is supplied to the amorphous silicon film 103, many Si—Ni groups are formed on the surface of the amorphous silicon film 103. As the supply of the nickel raw material gas to the amorphous silicon film 103 continues, the nickel adsorbed to the surface of the amorphous silicon film 103 diffuses into the interior of the amorphous silicon film 103, and the nickel concentration in the amorphous silicon film 103 increases, as shown in the lower view of FIG. 4.

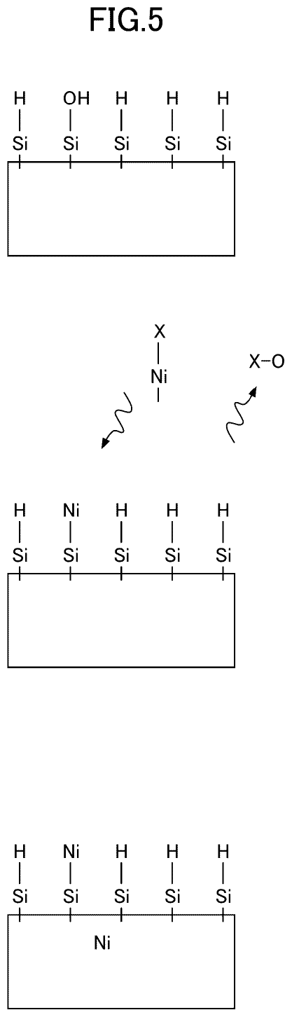

FIG. 5 is a schematic diagram showing another example of the surface reaction in the diffusion step S3. FIG. 5 shows the surface reaction in the diffusion step S3 when DHF is used as the processing liquid in the surface state changing step S2. The upper view of FIG. 5 is a view showing the surface state of the amorphous silicon film 103 before the diffusion step S3 is performed. The middle view of FIG. 5 is a view showing the surface state of the amorphous silicon film 103 after the first time has elapsed from the start of the diffusion step S3. The lower view of FIG. 5 is a view showing the surface state of the amorphous silicon film 103 after the second time has elapsed from the start of the diffusion step S3.

As shown in the upper view of FIG. 5, when DHF is supplied to the amorphous silicon film 103, the ratio of Si—OH groups to Si—H groups on the surface of the amorphous silicon film 103 decreases. As described above, there is a greater difficulty for the reaction for forming Si—Ni groups from Si—H groups and the nickel raw material gas to proceed than that for the reaction for forming Si—Ni groups from Si—OH groups and the nickel raw material gas to proceed. Therefore, as shown in the middle view of FIG. 5, even when the nickel raw material gas is supplied to the amorphous silicon film 103, Si—Ni groups are not easily formed on the surface of the amorphous silicon film 103. Even when the nickel raw material gas is continuously supplied to the amorphous silicon film 103, as shown in the lower view of FIG. 5, nickel does not easily diffuse into the interior of the amorphous silicon film 103, and the nickel concentration in the amorphous silicon film 103 is low.

The crystallization step S4 is performed after the diffusion step S3. In the crystallization step S4, as shown in the lowermost view of FIG. 2, the nickel-containing amorphous silicon film 103a is crystallized by Metal-Induced Lateral Crystallization (MILC) to form a polycrystalline silicon film 105. In this case, the polycrystalline silicon film 105 can be formed by metal-induced lateral crystallization with nickel at a low concentration. In the crystallization step S4, for example, the substrate 101 is heated to a first temperature, and the nickel-containing amorphous silicon film 103a is crystallized by metal-induced lateral crystallization in which nickel diffused into the nickel-containing amorphous silicon film 103a serves as a nucleus, to form the polycrystalline silicon film 105. The first temperature is, for example, 500° C. or higher and 600° C. or lower. The crystallization step S4 is performed in, for example, an inert gas atmosphere at normal pressure. The crystallization step S4 may be performed at reduced pressure. For example, the crystallization step S4 is performed continuously in the same processing chamber as that in the diffusion step S3. The crystallization step S4 may be performed in a processing chamber different from that in the diffusion step S3. After the crystallization step S4, a step of removing nickel remaining in the surface layer or the interior of the polycrystalline silicon film 105 by, for example, gettering may be performed.

Thus, the polycrystalline silicon film 105 can be formed on the substrate 101.

As described above, according to the film forming method of the present embodiment, after the surface state of the amorphous silicon film 103 is changed in the surface state changing step S2, nickel is diffused into the amorphous silicon film 103 in the diffusion step S3. This varies the ease with which the surface reaction in the diffusion step S3 proceeds, making it possible to control the nickel concentration in the amorphous silicon film 103.

In the above embodiment, a case of forming the polycrystalline silicon film 105 on the substrate 101 has been described, but this is a non-limiting example. For example, the film forming method of the present disclosure can also be applied to a case of forming the polycrystalline silicon film 105 on the inner surface of a recess, such as a hole, a trench, or the like, that is present in the surface of the substrate 101. In this case, by diffusing nickel into the amorphous silicon film 103 using the nickel raw material gas, it is possible to reduce variation in the amount of nickel diffusion in the depth direction of the recess. Therefore, the polycrystalline silicon film 105, in which variation in the grain size in the depth direction of the recess is small, can be formed.

### FILM FORMING APPARATUS

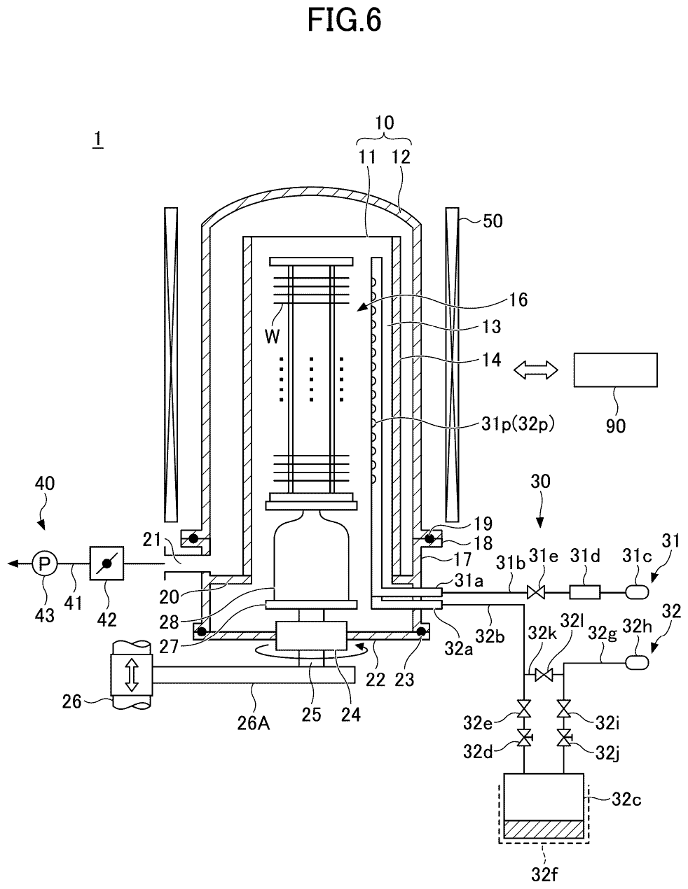

Referring to FIG. 6, an example of a film forming apparatus 1 capable of performing the preparation step S1, the diffusion step S3, and the crystallization step S4 of the film forming method according to the present embodiment will be described. FIG. 6 is a cross-sectional view showing the film forming apparatus 1 according to the present embodiment.

The film forming apparatus 1 includes a processing chamber 10, a gas supply part 30, a gas exhaust part 40, a heating part 50, and a controller 90.

The processing chamber 10 has a double-tube structure composed of a cylindrical inner tube 11 and a ceiled outer tube 12 placed concentrically on the outer side of the inner tube 11. The inner tube 11 and the outer tube 12 are formed of, for example, quartz. The processing chamber 10 is configured to house a boat 16.

A housing part 13 is formed along the longitudinal direction (vertical direction) of the inner tube 11 on one side of the inner tube 11. The housing part 13 is a region located within a protruding part 14 created by extending a part of the side wall of the inner tube 11 outward. Supply tubes 31a and 32a, which will be described later, are housed in the housing part 13.

The lower end of the processing chamber 10 is supported by a cylindrical manifold 17 formed of, for example, stainless steel. A flange 18 is formed on the upper end of the manifold 17. The flange 18 supports the lower end of the outer tube 12. A seal member 19, such as an O-ring and the like, is provided between the flange 18 and the lower end of the outer tube 12.

An annular support part 20 is provided on the inner wall of an upper part of the manifold 17. The support part 20 supports the lower end of the inner tube 11. A gas exhaust port 21 is provided in the side wall of an upper part of the manifold 17 above the support part 20. A cover 22 is attached to an opening at the lower end of the manifold 17 hermetically via a seal member 23, such as an O-ring and the like. The cover 22 is formed of, for example, stainless steel.

A rotating shaft 25 is provided in the center of the cover 22 via a magnetic fluid seal 24 so as to penetrate the cover 22. The lower end of the rotating shaft 25 is rotatably supported by an arm 26A of a lifting mechanism 26 formed of a boat elevator. A rotating plate 27 is provided on the upper end of the rotating shaft 25. A boat 16 is placed on the rotating plate 27 via a thermal insulating cylinder 28 made of quartz.

The boat 16 supports a plurality of (for example, 25 to 200) substrates W substantially horizontally at intervals in the vertical direction. The substrate W is, for example, a semiconductor wafer. The boat 16 rotates integrally with the rotating shaft 25. The boat 16 is vertically moved integrally with the cover 22 by raising and lowering of the arm 26A, and is inserted into and removed from the interior of the processing chamber 10.

The gas supply part 30 is configured to introduce various gases into the inner tube 11. The various gases include gases used in the film forming method according to the present embodiment. The gas supply part 30 includes a silicon raw material supply part 31 and a nickel raw material supply part 32.

The silicon raw material supply part 31 includes a supply tube 31a in the processing chamber 10 and a supply path 31b outside the processing chamber 10. A silicon raw material source 31c, a mass flow controller 31d, and an opening/closing valve 31e are provided on the supply path 31b in an order from the upstream side to the downstream side in the gas flow direction. The supply timing of a silicon-containing gas in the silicon raw material source 31c is controlled by the opening/closing valve 31e, and the flow rate thereof is regulated to a predetermined value by the mass flow controller 31d. The silicon-containing gas flows into the supply tube 31a through the supply path 31b, and is discharged into the processing chamber 10 from the supply tube 31a.

The nickel raw material supply part 32 includes a supply tube 32a in the processing chamber 10, and a supply path 32b outside the processing chamber 10. A raw material tank 32c, a regulating valve 32d, and an opening/closing valve 32e are provided on the supply path 32b in an order from the upstream side to the downstream side in the gas flow direction. The raw material tank 32c contains a nickel raw material. The nickel raw material is a raw material that is liquid at room temperature or a raw material that is solid at room temperature. A heater 32f is provided on the circumference of the raw material tank 32c. The heater 32f heats the nickel raw material in the raw material tank 32c. Thus, the liquid nickel raw material is vaporized or the solid nickel raw material is sublimated to produce a nickel raw material gas.

The nickel raw material supply part 32 includes a carrier gas tube 32g inserted into the raw material tank 32c from above. A carrier gas source 32h, an opening/closing valve 32i, and a regulating valve 32j are provided on the carrier gas tube 32g in an order from the upstream side to the downstream side in the gas flow direction. Thus, the carrier gas in the carrier gas source 32h is supplied into the raw material tank 32c with the supply timing thereof controlled by the opening/closing valve 321 and the flow rate thereof adjusted to a predetermined value by the regulating valve 32j. The carrier gas, together with the nickel raw material gas in the raw material tank 32c, flows into the supply tube 32a through the supply path 32b with the supply timing thereof controlled by the opening/closing valve 32e and the flow rate thereof regulated to a predetermined value by the regulating valve 32d. The nickel raw material gas and the carrier gas flowing into the supply tube 32a are discharged into the processing chamber 10 from the supply tube 32a.

A bypass path 32k may be provided to connect the upstream side of the opening/closing valve 32i on the carrier gas tube 32g and the downstream side of the opening/closing valve 32e on the supply path 32b. A bypass valve 321 may be provided on the bypass path 32k.

The supply tubes 31a and 32a are fixed to the manifold 17. The supply tubes 31a and 32a are formed of, for example, quartz. The supply tubes 31a and 32a extend linearly in the vertical direction at close positions in the inner tube 11, and are bent in an L-letter shape and extend horizontally in the manifold 17 to thereby penetrate the manifold 17. The supply tubes 31a and 32a are provided side by side along the circumferential direction of the inner tube 11, and are formed at the same height.

A plurality of gas holes 31p and 32p are provided in parts of the supply tubes 31a and 32a located in the inner tube 11, respectively. The gas holes 31p and 32p are formed at predetermined intervals along the extending direction of the supply tubes 31a and 32a, respectively. The gas holes 31p and 32p discharge gas in the horizontal direction. The interval between the gas holes 31p themselves and 32p themselves is set to be equal to, for example, the interval between the substrates W supported by the boat 16. The positions of the gas holes 31p and 32p in the height direction are set at intermediate positions between the substrates W adjacent in the vertical direction. In this case, the gas holes 31p and 32p can efficiently supply gas to the facing surfaces of adjacent substrates W.

The gas supply part 30 may mix a plurality of types of gases and discharge the mixed gas from one supply tube. For example, the supply tubes 31a and 32a may be configured to discharge inert gas. The supply tubes 31a and 32a may have different shapes and positionings. The gas supply part 30 may further include a supply tube for supplying another gas in addition to the silicon-containing gas and the nickel raw material gas.

The gas exhaust part 40 includes a gas exhaust path 41, a pressure regulating valve 42, and a vacuum pump 43. The gas exhaust path 41 is connected to the gas exhaust port 21. The pressure regulating valve 42 and the vacuum pump 43 are provided partway on the gas exhaust path 41. The vacuum pump 43 is provided on the downstream side of the pressure regulating valve 42 in the gas flow direction. The gas exhaust flow rate of the gas in the processing chamber 10 is controlled by the pressure regulating valve 42, and the gas is exhausted from the processing chamber 10 by the vacuum pump 43.

The heating part 50 has a cylindrical shape and is provided on the circumference of the outer tube 12. The heating part 50 heats each substrate W in the processing chamber 10. The heating part 50 includes, for example, a heater.

The controller 90 is an electronic circuit such as a Central Processing Unit (CPU), a Field Programmable Gate Array (FPGA), an Application Specific Integrated Circuit (ASIC), and the like. The controller 90 performs various control operations described herein by executing instruction codes stored in a memory or by being designed as a circuit for special applications.

### OPERATION OF FILM FORMING APPARATUS

The operation in a case of performing the diffusion step S3 and the crystallization step S4 of the film forming method according to the present embodiment with the film forming apparatus 1 will be described below.

First, the controller 90 controls the lifting mechanism 26 to load the boat 16 supporting a plurality of substrates W into the processing chamber 10, and hermetically closes and seals the opening at the lower end of the processing chamber 10 with the cover 22. Each substrate W is, for example, the substrate 101 that has undergone the surface state changing step S2. For example, the surface state changing step S2 is performed in a coating device provided separately from the film forming apparatus 1.

Next, the controller 90 controls the gas supply part 30, the gas exhaust part 40, and the heating part 50 to perform the diffusion step S3. Specifically, the controller 90 controls the gas exhaust part 40 to depressurize the interior of the processing chamber 10 to a predetermined pressure, and controls the heating part 50 to adjust and maintain the temperature of the substrates W at a predetermined temperature. Next, the controller 90 controls the gas supply part 30 to supply the nickel raw material gas into the processing chamber 10. As a result, nickel diffuses into the amorphous silicon film 103 to form the nickel-containing amorphous silicon film 103a.

Next, the controller 90 controls the gas supply part 30, the gas exhaust part 40, and the heating part 50 to perform the crystallization step S4. Specifically, the controller 90 first controls the gas supply part 30 to supply inert gas into the processing chamber 10, controls the gas exhaust part 40 to adjust the pressure in the processing chamber 10 to a predetermined pressure, and controls the heating part 50 to adjust and maintain the temperature of the substrates W at a predetermined temperature. Thus, the nickel-containing amorphous silicon film 103a is crystallized by metal-induced lateral crystallization to form the polycrystalline silicon film 105.

Next, the controller 90 raises the pressure in the processing chamber 10 to the open-air pressure, lowers the temperature in the processing chamber 10 to an unloading temperature, and then controls the lifting mechanism 26 to unload the boat 16 from the processing chamber 10.

### EXPERIMENTAL RESULTS

### Experiment 1

In Experiment 1, the preparation step S1, the surface state changing step S2, and the diffusion step S3 were performed in this order, and then the nickel concentration in the amorphous silicon film was measured. In Experiment 1, the surface state changing step S2 was performed in a coating device provided separately from the film forming apparatus 1. In the surface state changing step S2, one of the following conditions was selected: supplying no processing liquid to the amorphous silicon film (hereinafter, also referred to as “un-washing”); supplying DHF and APM in this order to the amorphous silicon film (hereinafter, also referred to as “APM”); and supplying DHF to the amorphous silicon film (hereinafter, also referred to as “DHF”). In Experiment 1, the diffusion step S3 was performed in the film forming apparatus 1. In the diffusion step S3, the substrate temperature was set to 250° C., and the flow rate of the nickel raw material gas was set to 5 sccm. The nickel concentration was measured by Total Reflection X-Ray Fluorescence (TXRF).

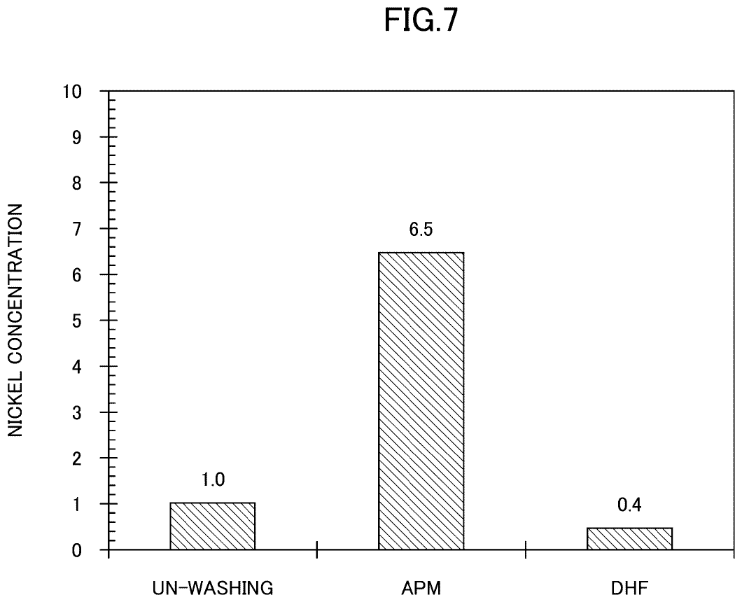

FIG. 7 is a diagram showing an example of a result of comparison of nickel concentration in the amorphous silicon film. FIG. 7 shows the nickel concentration in the amorphous silicon film in the cases of “APM” and “DHF” as relative values by regarding the nickel concentration in the amorphous silicon film in the case of “un-washing” as 1.

As shown in FIG. 7, the nickel concentration in the amorphous silicon film in the case of “APM” is higher than that in the case of “un-washing”, and the nickel concentration in the amorphous silicon film in the case of “DHF” is lower than that in the case of “un-washing”. This result indicates that supplying DHF and APM in this order to the amorphous silicon film increased the nickel concentration in the amorphous silicon film, and that supplying DHF to the amorphous silicon film decreased the nickel concentration in the amorphous silicon film. That is, it was indicated that the nickel concentration in the amorphous silicon film could be controlled by diffusing nickel into the amorphous silicon film after changing the surface state of the amorphous silicon film.

### Experiment 2

In Experiment 2, the nickel concentration in the amorphous silicon film was measured after the preparation step S1, the surface state changing step S2, and the diffusion step S3 were performed in this order as in Experiment 1. In Experiment 2, the effect of the temperature at which nickel was diffused into the amorphous silicon film in the diffusion step S3 on the nickel concentration in the amorphous silicon film in the case of performing the surface state changing step S2 under the condition of supplying DHF and APM in this order to the amorphous silicon film was evaluated.

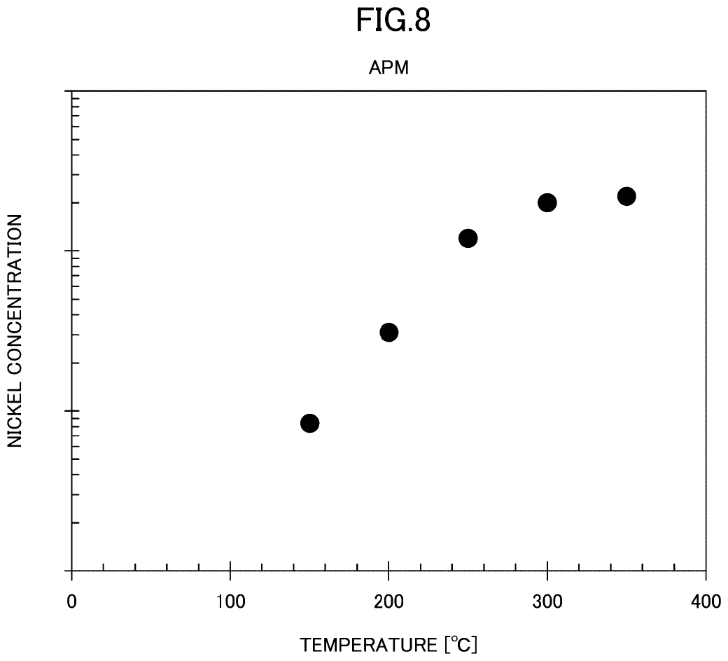

FIG. 8 is a diagram showing an example of the temperature dependency of the nickel concentration in the amorphous silicon film. In FIG. 8, the horizontal axis indicates the temperature [° C.] at which nickel was diffused into the amorphous silicon film, and the vertical axis indicates the nickel concentration in the amorphous silicon film by logarithmic values.

As shown in FIG. 8, the higher the temperature at which nickel was diffused into the amorphous silicon film, the higher the nickel concentration in the amorphous silicon film. This result indicates that the nickel concentration in the amorphous silicon film could be controlled by supplying DHF and APM in this order to the amorphous silicon film in the surface state changing step S2, and adjusting the temperature at which nickel was diffused into the amorphous silicon film in the diffusion step S3.

### Experiment 3

In Experiment 3, the nickel concentration in the amorphous silicon film was measured after the preparation step S1, the surface state changing step S2, and the diffusion step S3 were performed in this order in the film forming apparatus 1 as in Experiment 1. In Example 3, the effect of the temperature at which nickel was diffused into the amorphous silicon film in the diffusion step S3 on the nickel concentration in the amorphous silicon film in the case of performing the surface state changing step S2 under the condition of supplying DHF to the amorphous silicon film was evaluated.

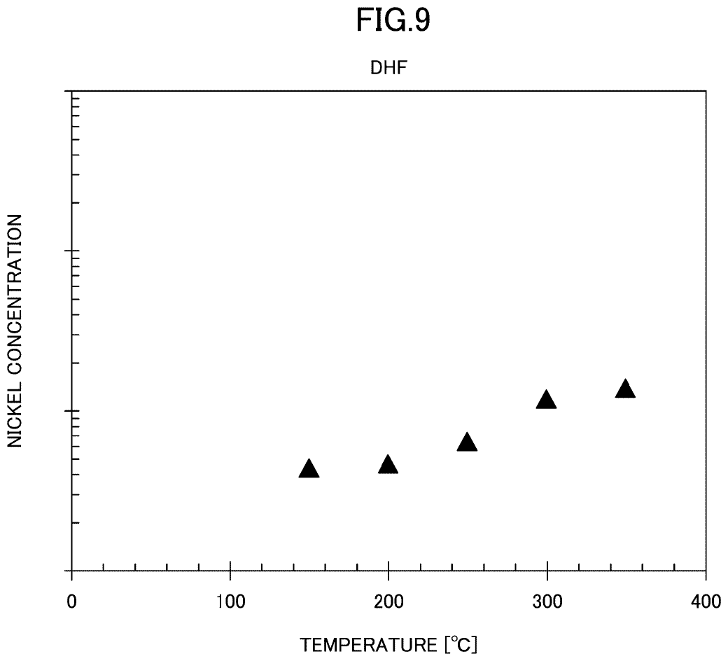

FIG. 9 is a diagram showing another example of the temperature dependency of the nickel concentration in the amorphous silicon film. In FIG. 9, the horizontal axis indicates the temperature [° C.] at which nickel was diffused into the amorphous silicon film, and the vertical axis indicates the nickel concentration in the amorphous silicon film as logarithmic values.

As shown in FIG. 9, the higher the temperature at which nickel was diffused into the amorphous silicon film, the higher the nickel concentration in the amorphous silicon film. This result indicates that the nickel concentration in the amorphous silicon film can be controlled by supplying DHF to the amorphous silicon film in the surface state changing step S2 and adjusting the temperature at which nickel was diffused into the amorphous silicon film in the diffusion step S3.

The embodiments disclosed herein are exemplary in all respects and should be considered non-limiting. Various omissions, replacements, and modifications may be applied to the above embodiments without departing from the scope and spirit of the appended claims.

In the above embodiments, the case where the film forming apparatus is a batch-type apparatus that processes a plurality of substrates at a time has been described. However, the present disclosure is not limited to this case. For example, the film forming apparatus may be a single wafer-type apparatus that processes one substrate at a time.

What is claimed is:

1. A film forming method, comprising:
preparing a substrate having an amorphous silicon film on a surface of the substrate;
changing a surface state of the amorphous silicon film; and
after the changing, diffusing nickel into the amorphous silicon film by supplying a nickel raw material gas to the amorphous silicon film.

2. The film forming method according to claim 1,
wherein the changing includes changing a ratio of Si—OH groups to Si—H groups on a surface of the amorphous silicon film.

3. The film forming method according to claim 2,
wherein the changing includes adjusting the ratio by supplying a processing liquid to the amorphous silicon film.

4. The film forming method according to claim 3,
wherein the processing liquid contains APM, and
the changing includes increasing the ratio.

5. The film forming method according to claim 3,
wherein the processing liquid contains DHF, and
the changing includes reducing the ratio.

6. The film forming method according to claim 1, further comprising:
forming a polycrystalline silicon film by heating the amorphous silicon film and crystallizing the amorphous silicon film by metal-induced lateral crystallization in which the nickel diffused in the amorphous silicon film serves as a nucleus.

7. The film forming method according to claim 1,
wherein the diffusing includes producing the nickel raw material gas by vaporizing a nickel raw material when the nickel raw material is liquid, or by sublimating the nickel raw material when the nickel raw material is solid.

8. The film forming method according to claim 7,
wherein the nickel raw material is Ni(C₂H₅C₅H₄)₂, Ni(PF₃)₄, (C₃H₅)(C₅H₅)Ni, Ni(CO)₄, or Ni(CH₃C₅H₄)₂.

9. The film forming method according to claim 1,
wherein a recess is formed in the surface of the substrate, and
the preparing includes forming the amorphous silicon film on an inner surface of the recess.

10. The film forming method according to claim 1,
wherein the preparing includes forming the amorphous silicon film on the surface of the substrate in a same processing chamber as that in the diffusing.

11. The film forming method according to claim 6,
wherein the diffusing and the forming of the polycrystalline silicon film are performed in a same processing chamber.
